(19) United States
(12) Patent Application Publication
(10) Pub. No.: US 2026/0033043 A1
(43) Pub. Date: Jan. 29, 2026

(54) LIGHT EMITTING DIODE AND LIGHT EMITTING DEVICE

(71) Applicant: HUBEI SAN'AN OPTOELECTRONICS CO., LTD., Ezhou (CN)

(72) Inventors: GUANGYAO WU, Ezhou (CN); LING-YUAN HONG, Ezhou (CN); JIANGBIN ZENG, Ezhou (CN); KAI ZHAO, Ezhou (CN); YANLI WAN, Ezhou (CN); QING WANG, Ezhou (CN); JIN XU, Ezhou (CN)

(21) Appl. No.: 19/283,233

(22) Filed: Jul. 29, 2025

(30) Foreign Application Priority Data
Jul. 29, 2024 (CN) 202411027487.2
Nov. 27, 2024 (CN) 202411721840.7

(51) Int. Cl. H10H 20/831

(52) U.S. Cl. CPC H10H 20/831

(57) ABSTRACT

Provided is a light emitting diode (LED), which includes: a semiconductor stack, including a first semiconductor layer, an active layer, and a second semiconductor layer sequentially stacked in that order; an insulating layer, disposed on the semiconductor stack and having a first opening and a second opening; a first pad electrode, disposed on the insulating layer and electrically connected to the first semiconductor layer via the first opening; and a second pad electrode, disposed on the insulating layer and electrically connected to the second semiconductor layer via the second opening; where in a top view of the LED, a ratio of an area of an overlapping region (S1) between a projection of the first pad electrode on the semiconductor stack and a projection of the second semiconductor layer on the semiconductor stack to an area of the first pad electrode is less than 40%.

### TECHNICAL FIELD

The present disclosure relates to the field of semiconductor manufacturing technologies, and particularly to a light emitting diode (LED) and a light emitting device.

### BACKGROUND

LEDs are used in large-scale backlight units (BLUs), general lighting, and electronic devices, as well as in small household appliances and decorative interior products. Beyond serving merely as light sources, the LEDs are now employed for a wide range of purposes, such as conveying information and evoking aesthetic appeal.

### SUMMARY

An embodiment of the present disclosure provides an LED, which includes: a semiconductor stack, including a first semiconductor layer, an active layer, and a second semiconductor layer, which are sequentially stacked in that order; an insulating layer, disposed on the semiconductor stack and having a first opening and a second opening; a first pad electrode, disposed on the insulating layer and electrically connected to the first semiconductor layer via the first opening; and a second pad electrode, disposed on the insulating layer and electrically connected to the second semiconductor layer via the second opening; where in a top view of the LED, a ratio of an area of an overlapping region (S1) between a projection of the first pad electrode on the semiconductor stack and a projection of the second semiconductor layer on the semiconductor stack to an area of the first pad electrode is less than 40%.

An embodiment of the present disclosure provides a light emitting device, which includes: a substrate; LEDs, disposed on the substrate; and an encapsulation layer, covering the LEDs.

### BRIEF DESCRIPTION OF DRAWINGS

FIG. 1 illustrates a schematic plan view of an LED according to an embodiment of the present disclosure.

FIG. 2 illustrates another schematic plan view of the LED in FIG. 1.

FIG. 3 illustrates a schematic enlarged view of regions I, II, and III in FIG. 2.

FIG. 4 illustrates a schematic cross-sectional view of FIG. 1.

FIG. 5 illustrates a schematic plan view of an LED according to another embodiment of the present disclosure.

FIG. 6 illustrates a schematic enlarged view of regions IV, V, and VI in FIG. 5.

FIG. 7 illustrates a schematic structural view of a light emitting device according to an embodiment of the present disclosure.

FIG. 8 illustrates a schematic plan view of an LED in the prior art.

### DETAILED DESCRIPTION OF EMBODIMENTS

To keep the specification concise, projections mentioned hereinafter are all based on a semiconductor stack as a reference plane and are projections along a third direction Z.

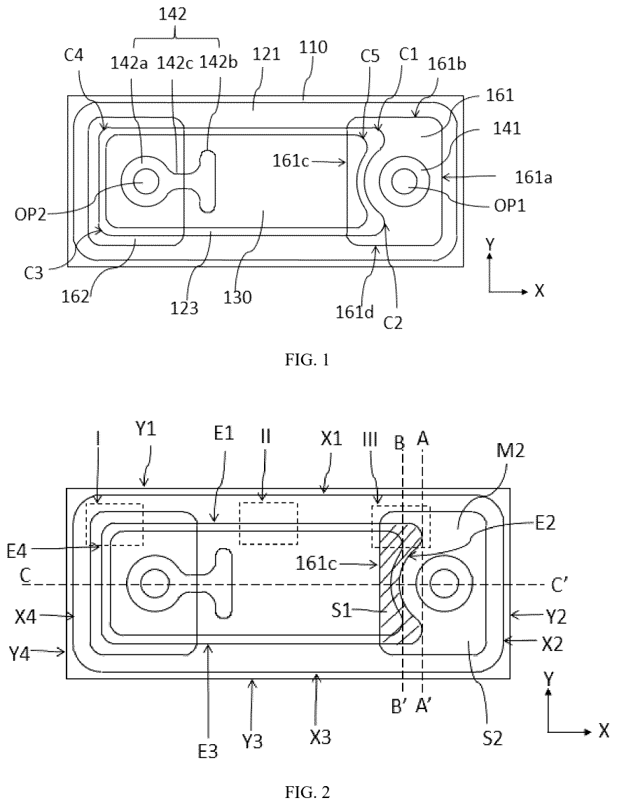

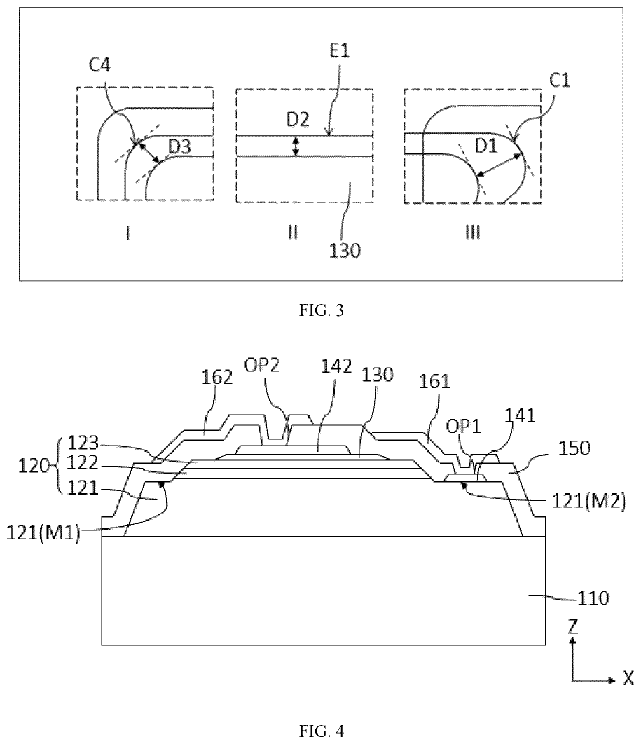

FIGS. 1 and 2 illustrate schematic plan views an LED of an embodiment of the present disclosure. FIG. 3 illustrates a schematic enlarged view of regions I, II, and III in FIG. 2. FIG. 4 illustrates a schematic cross-sectional view of FIG. 1.

As shown in FIGS. 1 and 4, the LED of this embodiment includes a substrate 110, a semiconductor stack 120, a transparent conductive layer 130, a first contact electrode 141, a second contact electrode 142, an insulating layer 150, a first pad electrode 161, and a second pad electrode 162.

The substrate 110 may be an insulating substrate or a conductive substrate. The substrate 110 can serve as a growth substrate for the semiconductor stack 120 and may include a sapphire substrate, a silicon-carbide (SiC) substrate, a silicon (Si) substrate, a gallium-nitride (GaN) substrate, or an aluminum-nitride (AlN) substrate. Additionally, the substrate 110 may include multiple protrusions formed on at least part of an upper surface of the substrate 110. These protrusions of the substrate 110 may form regular or irregular patterns. For example, the substrate 110 may be a patterned sapphire substrate (PSS) having multiple protrusions on its upper surface. A thickness of the substrate 110 is generally in a range of about 100 μm to 200 μm.

As shown in FIG. 2, the substrate 110 has a first edge Y1, a second edge Y2, a third edge Y3, and a fourth edge Y4, which are connected sequentially in that order. The edges of the substrate 110 may be considered equivalent to edges of the LED. The first edge Y1 and the third edge Y3 extend along a first direction X, and the second edge Y2 and the fourth edge Y4 extend along a second direction Y. A thickness direction of the substrate 110 is the third direction Z.

The semiconductor stack 120 is disposed on the substrate 110. An area of a lower surface of the semiconductor stack 120 may be smaller than an area of an upper surface of the substrate 110, so that a part of the upper surface of the substrate 110 is exposed along a periphery of the semiconductor stack 120. Some of protrusions on the upper surface of the substrate 110 are located between the semiconductor stack 120 and the substrate 110, while some protrusions not covered by the semiconductor stack 120 are exposed around the semiconductor stack 120.

The semiconductor stack 120 includes a first semiconductor layer 121, a second semiconductor layer 123 disposed on the first semiconductor layer 121, and an active layer 122 disposed between the first semiconductor layer 121 and the second semiconductor layer 123. The first semiconductor layer 121, the active layer 122, and the second semiconductor layer 123 are stacked sequentially along the third direction Z of the substrate 110. A total thickness of the semiconductor stack 120 is generally in a range of about 3 μm to 10 μm.

The first semiconductor layer 121, the active layer 122, and the second semiconductor layer 123 may include Group III-V nitride-based semiconductors, such as AlN, GaN, or InN. The first semiconductor layer 121 may include n-type impurities (e.g., Si, Ge, Sn), and the second semiconductor layer 123 may include p-type impurities (e.g., Mg, Sr, Ba). Of course, the first semiconductor layer 121 may include p-type impurities (e.g., Mg, Sr, Ba), and the second semiconductor layer 123 may include n-type impurities (e.g., Si, Ge, Sn). The active layer 122 may include a multi-quantum-well (MQW) structure, and a composition ratio of the nitride semiconductor may be adjusted to emit light with a desired wavelength. In this embodiment, the second semiconductor layer 123 is a p-type semiconductor layer.

As shown in FIG. 2, a surface of the second semiconductor layer 123 includes a first edge E1, a second edge E2, a third edge E3, and a fourth edge E4, which are connected sequentially in that order, as well as a first corner C1 connecting the first edge E1 and the second edge E2, a second corner C2 connecting the second edge E2 and the third edge E3, a third corner C3 connecting the third edge E3 and the fourth edge E4, and a fourth corner C4 connecting the fourth edge E4 and the first edge E1.

The first edge E1 and the third edge E3 extend along the first direction X, and the second edge E2 and the fourth edge E4 extend along the second direction Y. In an embodiment, the second edge E2 is composed of multiple curved segments and can be regarded as extending generally along the second direction Y; and the first edge E1, the third edge E3, and the fourth edge E4 are straight lines.

The semiconductor stack 120 includes a mesa M exposing a part of a surface of the first semiconductor layer 121. Specifically, the semiconductor stack 120 may be etched to remove the second semiconductor layer 123, the active layer 122, and a part of the first semiconductor layer 121, thereby forming the mesa M exposing the part of the surface of the first semiconductor layer 121. The mesa M may be located outside the second semiconductor layer 123 and surround the second semiconductor layer 123. In another embodiment, the mesa M may also be formed inside the semiconductor stack 120 (as a through-hole or through-groove) to expose part of the surface of the first semiconductor layer 121.

The mesa M includes a first region M1 and a second region M2. The first region M1 is distributed along the first edge E1, the third edge E3, and the fourth edge E4, and the second region M2 is distributed along the second edge E2.

As shown in FIGS. 1 and 4, the transparent conductive layer 130 is disposed on the second semiconductor layer 123. The transparent conductive layer 130 may be in ohmic contact with the second semiconductor layer 123. The transparent conductive layer 130 may be a light-transmitting conductive oxide layer, which may include conductive oxide such as indium tin oxide (ITO), zinc oxide (ZnO), zinc indium tin oxide (ZITO), zinc indium oxide (ZIO), zinc tin oxide (ZTO), gallium indium tin oxide (GITO), gallium indium oxide (GIO), gallium zinc oxide (GZO), aluminum-doped zinc oxide (AZO), or fluorine-doped tin oxide (FTO). The conductive oxide may also include various dopants.

In this embodiment, a thickness of the transparent conductive layer 130 is between 50 nm and 200 nm. A size of the LED is less than 300 μm×150 μm. If the thickness of the transparent conductive layer 130 is less than 50 nm, a current may not spread sufficiently, resulting in poor ESD capability of the LED. If the thickness of the transparent conductive layer 130 exceeds 200 nm, the transparent conductive layer 130 may absorb light and cause optical losses.

The first contact electrode 141 is disposed on the first semiconductor layer 121, specifically on the second region M2. The first contact electrode 141 is in ohmic contact with the first semiconductor layer 121 and serves to spread the current. In an embodiment, the first contact electrode 141 includes a metal layer in ohmic contact with the first semiconductor layer 121.

In an embodiment, the first contact electrode 141 may be formed as a block in the second region M2.

The first contact electrode 141 does not overlap the active layer 122 or the second semiconductor layer 123, so an insulating layer for insulating the first contact electrode 141 from the second semiconductor layer 123 is omitted. The first contact electrode 141 may be formed on the semiconductor stack 120 on which the transparent conductive layer 130 is formed, for example, by a lift-off process. In this case, the second contact electrode 142 described below may also be formed simultaneously.

The second contact electrode 142 is disposed on the transparent conductive layer 130 and is electrically connected to the transparent conductive layer 130, thereby assisting in current spreading within the second semiconductor layer 123.

The second contact electrode 142 may include a connection portion 142c and an extension portion 142b extending from the connection portion 142c.

To reduce light absorption caused by the second contact electrode 142, the second contact electrode 142 is disposed on a part of a region of the transparent conductive layer 130. A total area of the second contact electrode 142 does not exceed 2/10 of an area of the transparent conductive layer 130. The second contact electrode 142 may include a starting portion 142a, an extension portion 142b, and a connection portion 142c connecting the starting portion 142a and the extension portion 142b.

The extension portion 142b is wider than the starting portion 142a and the connection portion 142c, and the starting portion 142a is wider than the connection portion 142c. To spread the current, the extension portion 142b may take various shapes.

The first contact electrode 141 and the second contact electrode 142 may be formed in a same process using a same material, so they may have a same layer structure. For example, the first contact electrode 141 and the second contact electrode 142 may include an Al reflective layer and may include Au. Specifically, the first contact electrode 141 and the second contact electrode 142 may have a layer structure of Cr/Al/Ti/Ni/Ti/Ni/Au/Ti. In another embodiment, to reduce costs, the first contact electrode 141 and the second contact electrode 142 may not include Au.

The insulating layer 150 is disposed on the semiconductor stack 120. Specifically, the insulating layer 150 may cover the semiconductor stack 120, the transparent conductive layer 130, the first contact electrode 141, and the second contact electrode 142. The insulating layer 150 has a first opening OP1 and a second opening OP2. The first opening OP1 exposes a part of a surface of the first contact electrode 141, and the second opening OP2 exposes a part of a surface of the second contact electrode 142. Specifically, the second opening OP2 exposes a part of a surface of the starting portion 142a of the second contact electrode 142. A size of the first opening OP1 is smaller than an area of the first contact electrode 141, and a size of the second opening OP2 is smaller than an area of the starting portion 142a of the second contact electrode 142.

The insulating layer 150 includes a distributed Bragg reflector (DBR). The DBR may be formed by repeatedly stacking dielectric layers with different refractive indices, and the dielectric layers may include at least one of TiO₂, SiO₂, HfO₂, ZrO₂, Nb₂O₅, MgF₂. For example, the insulating layer 150 may have a structure in which TiO₂ layers and SiO₂ layers are alternately stacked. The DBR is designed to reflect light generated in the active layer 122, and multiple pairs of stacked layers are formed to improve the reflectivity of the LED. In this embodiment, the DBR may include 10 to 25 pairs of stacked layers. In addition to the DBR, the insulating layer 150 may further include additional insulating layers. For example, to improve the adhesion between the DBR and its underlying layer, the LED may further include an interface layer under the DBR, and a protective layer covering the DBR. The interface layer may be formed of, for example, a SiO₂ layer, and the protective layer may be formed of SiN. The layer formed of SiN, has excellent moisture resistance, thereby protecting the LED from moisture.

The insulating layer 150 may have a thickness of about 2 μm to 5 μm. A reflectivity of the DBR for light generated in the active layer 122 may be 90% or more, and by controlling a type, a thickness, and a stacking period of the dielectric layers forming the DBR, a reflectivity close to 100% can be achieved. Furthermore, the DBR may also have higher reflectivity for visible light other than the light generated in the active layer 122.

The first pad electrode 161 and the second pad electrode 162 are disposed on the insulating layer 150. The first pad electrode 161 is in contact with the first contact electrode 141 through the first opening OP1, thereby being electrically connected to the first semiconductor layer 121. The second pad electrode 162 is in contact with the second contact electrode 142 through the second opening OP2, thereby being electrically connected to the second semiconductor layer 123.

The first pad electrode 161 and the second pad electrode 162 may be formed in a same process using a same material, so they may have a same layer structure. A thickness of each of the first pad electrode 161 and the second pad electrode 162 may be thinner than a thickness of the insulating layer 150, for example, the thickness of each of the first pad electrode 161 and the second pad electrode 162 is about 2 μm. The thickness of each of the first pad electrode 161 and the second pad electrode 162 may also be thicker than the thickness of the insulating layer 150.

The first pad electrode 161 and the second pad electrode 162 are arranged along the first direction X.

In an embodiment, as shown in FIG. 1, a projection of the first pad electrode 161 on the semiconductor stack 120 covers projections of the first corner C1 and the second corner C2 on the semiconductor stack 120, and a projection of the second pad electrode 162 on the semiconductor stack 120 covers projections of the third corner C3 and the fourth corner C4 on the semiconductor stack 120. Specifically, the projection of the first pad electrode 161 on the semiconductor stack 120 covers a projection of the second edge E2 on the semiconductor stack 120, a projection of a part of the first edge E1 on the semiconductor stack 120, and a projection of a part of the third edge E3 on the semiconductor stack 120. The projection of the second pad electrode 162 covers a projection of the fourth edge E4 on the semiconductor stack 120, a projection of a part of the first edge E1 on the semiconductor stack 120, and a projection of a part of the third edge E3 on the semiconductor stack 120. This increases surface areas of the first pad electrode 161 and the second pad electrode 162, thereby greatly improving the thrust of the first pad electrode 161 and the second pad electrode 162 during a subsequent die-bonding process, i.e., increasing the bonding force between the first pad electrode 161 and the substrate 110 and between the second pad electrode 162 and the substrate 110. This can avoid the LED from detaching from the substrate 110, improving reliability of the LED.

In an embodiment, as shown in FIG. 1, the first pad electrode 161 has a first long side 161a, a first short side 161b, a second long side 161c, and a second short side 161d, which are connected sequentially in that order. An extending direction of each of the first short side 161b and the second short side 161d is the same as an extending direction (the first direction X) of the first edge E1 of the second semiconductor layer 123, and an extending direction of the first long side 161a is the same as an extending direction (the second direction Y) of the second edge E2 of the second semiconductor layer 123. Projections of the first long side 161a, the first short side 161b, and the second short side 161d of the first pad electrode 161 are located within the mesa M. Similarly, projections of a first long side, a first short side, and a second short side of the second pad electrode 162 are located within the mesa M. A projection of the second long side 161c of the first pad electrode 161 is located within the second semiconductor layer 123. This design ensures that the first pad electrode 161 and the second pad electrode 162 do not extend onto a region of the substrate 110 not covered by the semiconductor stack 120. Therefore, during a dicing process of the LED, a region where the insulating layer 150 may crack in the region of the substrate 110 not covered by the semiconductor stack 120 will not be covered by the first pad electrode 161 or the second pad electrode 162, which facilitates the identification of a cracked region in a subsequent automated optical inspection (AOI) inspection, improving the yield of the LED and preventing cracked LEDs from entering a die-bonding stage. This also prevents solder paste from entering the cracked region after die-bonding, which could cause the LED to leak current, thereby improving device reliability.

As shown in FIG. 8, FIG. 8 illustrates a schematic plan view of an LED in the prior art, in which a transparent conductive layer and an insulating layer are omitted for simplicity. In the prior art, to maximize a light-emitting area of the LED, a second region M2 of a mesa is usually located at a corner between a second edge Y2 and a third edge Y3 of the LED. An overlapping area between a projection of first pad electrode 161 and a projection of a second semiconductor layer 123 is defined as a region S1. An overlapping area between the projection of first pad electrode 161 and a projection of a first semiconductor layer 121 (i.e., a second region M2 of the mesa) is defined as a region S2. The regions S1 and S2 are arranged along the second direction Y. As a size of the LED becomes smaller, the size of the LED is less than 300 μm×150 μm, especially with a short edge being less than 150 μm, an area of each of the pad electrodes is also limited and becomes smaller. Due to the limited area of the pad electrodes and the need for the second region M2 of the mesa to accommodate the first contact electrode 161 thereon, areas of the regions S1 and S2 are approximately equal. However, the regions S1 and S2 of the approximately equal areas are mainly arranged along the second direction Y, and the tension of the solder paste or other die-bonding materials will pull the LED along the second direction Y, causing the LED to easily shift or tilt in the second direction Y, thereby greatly affecting the display effect on a client side.

In this application, referring to FIGS. 1 and 2, the second region M2 of the mesa is symmetrical with respect to a virtual central parallel line C, and the first contact electrode 141 disposed on the second region M2 of the mesa is symmetrical with respect to the virtual central parallel line C. The first opening OP1 of the insulating layer 150 formed on the first contact electrode 141 and exposing a part of a surface of the first contact electrode 141 is also symmetrical with respect to the virtual central parallel line C. The virtual central parallel line C is parallel to each of the first edge Y1 and the third edge Y3 of the substrate 110, and is located at a middle position between the first edge Y1 and the third edge Y3 of the substrate 110, or the virtual central parallel line C is located at a middle position between the first edge Y1 and the third edge Y3 of the LED. As shown in FIGS. 1 and 2, the second region M2 of the mesa is defined by: a part of the first edge X1 of the first semiconductor layer 121, the second edge X2, a part of the third edge X3, and an extension line of the second long side 161c of the first pad electrode 161 along the second direction Y. In an embodiment, the LED is symmetrical with respect to the virtual central parallel line C.

Referring to FIGS. 1 and 2, an overlapping area between a projection of the first pad electrode 161 and a projection of the second semiconductor layer 123 is defined as a region S1. An overlapping area between the projection of first pad electrode 161 and a projection of the first semiconductor layer 121 (the mesa M) is defined as a region S2. These overlapping areas S1 and S2 are primarily arranged along the first direction X and exhibit symmetry about the virtual central parallel line C. The tension of solid crystal materials such as solder paste is mainly influenced by the areas of the first pad electrode 161 and the second pad electrode 162 in the first direction X (the areas of the first pad electrode 161 and the second pad electrode 162 are equal, and the tension is equally distributed in the first direction X), but it is not influenced by the arrangement of the overlapping area S1 and the overlapping area S2 along the first direction X. On the other hand, in the second direction Y, because the overlapping area S1 and the overlapping area S2 are symmetrical along the virtual central parallel line C, the tension of the solid crystal materials such as solder paste in the second direction Y is equally distributed, this effectively prevents any pulling force on the light-emitting diode that could cause misalignment or tilting along the second direction Y.

In an embodiment, referring to FIGS. 1 and 2, an area of the region S1 is smaller than an area of the region S2. More specifically, a ratio of the area of the region S1 to an area of the first pad electrode 161 is less than 40%, and a ratio of the area of the region S2 to the area of the first pad electrode 161 is greater than 60%. Theoretically, the area of the first pad electrode 161 is equal to a sum of the areas of the regions S1 and S2. In an embodiment, the ratio of the area of the region S1 to the area of the first pad electrode 161 is less than 30%, and the ratio of the area of the region S2 to the area of the first pad electrode 161 is greater than 70%. By making the area of the region S1 much smaller than the area of the region S2, the shifting or tilting probability of the LED can be reduced. If a size of the LED is greater than 300 μm×150 μm, the same effect can be achieved by making the area of the region S1 greater than the area of the region S2. However, in this application, the size of the LED is limited (less than 300 μm×150 μm), and if the area of the region S1 is made greater than the area of the region S2, the area of the first contact electrode 161 would be too small to form a good ohmic contact.

In an embodiment, referring to FIGS. 1 and 2, a fillet radius of the first corner C1 or the second corner C2 is greater than 2 μm. The first corner C1 of the second semiconductor layer 123 has an extension line A perpendicular to the first short side 161b of the first pad electrode 161. A minimum spacing between the first corner C1 and the first long side 161a of the first pad electrode 161 is a spacing between the extension line A of the first corner C1 and the first long side 161a of the first pad electrode 161. The extension line A overlaps the first contact electrode 141, but does not overlap the first opening OP1 of the insulating layer 150. Due to the limitation of the short side of the LED, in the embodiments of this application, the short side of the LED is less than 150 μm. Therefore, it is necessary to ensure that the extension line A overlaps the first contact electrode 141, but does not overlap the first opening OP1 of the insulating layer 150, and that the fillet radius of the first corner C1 or the second corner C2 is greater than 2 μm, so as to ensure that the first corner C1 or the second corner C2 does not have a sharp corner, allowing a sufficient space for current diffusion. If a sharp corner appears at the first corner C1 or the second corner C2, the ESD capability at this location may be poor, leading to a tip leakage effect.

In an embodiment, referring to FIGS. 1 and 2, the transparent conductive layer 130 includes a fifth corner C5 adjacent to the first corner C1 of the second semiconductor layer 123, and a fillet radius of the fifth corner C5 is greater than 1 μm. The fifth corner C5 has an extension line B perpendicular to the first short side 161b of the first pad electrode 161. A minimum spacing between the fifth corner C5 and the first long side 161a of the first pad electrode 161 is a spacing between the extension line B of the fifth corner C5 and the first long side 161a of the first pad electrode 161. The extension line B does not overlap the first contact electrode 141, and does not overlap the first opening OP1 of the insulating layer 150. This design allows the LED to achieve a maximum light-emitting area despite the limitation of the short side, while preventing sharp corners at the first corner C1, the second corner C2, and the fifth corner C5, which could lead to poor ESD capability and tip leakage effects.

In an embodiment, referring to FIGS. 1 and 2, the spacing between the extension line A and the first long side 161a of the first pad electrode 161 is greater than one-half of a length of the first short side 161b of the first pad electrode 161. A length of the first edge E1 of the second semiconductor layer 123 covered by the projection of the first pad electrode 161 is less than one-half of the length of the first short side 161b of the first pad electrode 161.

In an embodiment, as shown in FIG. 3, FIG. 3 illustrates a schematic enlarged view of regions I, II, and III in FIG. 2, a spacing between the first corner C1 and the transparent conductive layer 130 is a first spacing D1, a spacing between the first edge E1 and the transparent conductive layer 130 is a second spacing D2, and a spacing between the fourth corner C4 and the transparent conductive layer 130 is a third spacing D3. The first spacing D1 is greater than the second spacing D2, and the third spacing D3 is greater than the second spacing D2. The first spacing D1 is between 1 μm and 5 μm, and the second spacing D2 is between 0 μm and 4 μm. If the second spacing D2 is 0 μm, the LED may leak current, reducing reliability.

However, since the size of the LED is less than 300 μm×150 μm, the light emitting area (i.e., an area of the active layer 122, which is equal to an area of the second semiconductor layer 123) is also becoming smaller. Consequently, an area of the transparent conductive layer 130 disposed on the second semiconductor layer 123 is also limited. To allow the transparent conductive layer 130 to spread the current as much as possible, one approach is to increase a thickness of the transparent conductive layer 130 (keeping the thickness of the transparent conductive layer 130 within the range of 50 nm to 200 nm), and the other approach is to minimize a spacing between the transparent conductive layer 130 and the second semiconductor layer 123 to maximize the area of the transparent conductive layer 130.

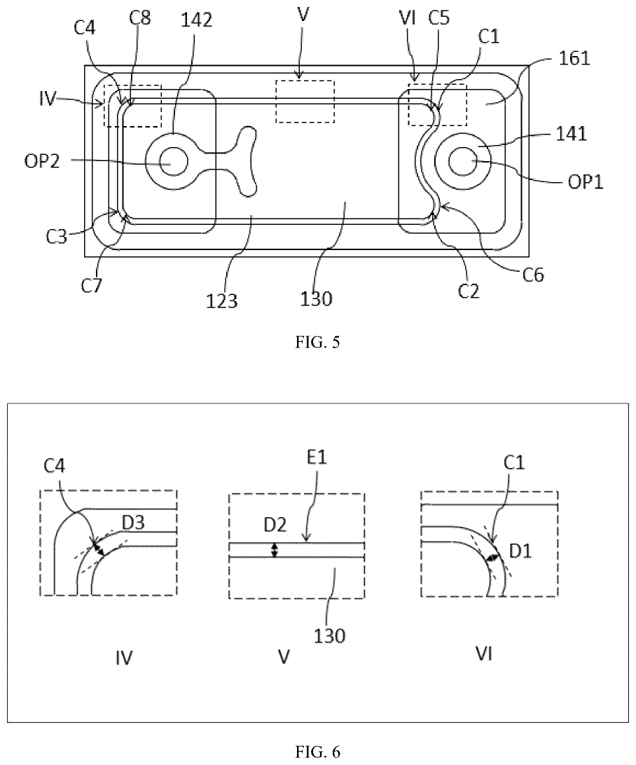

In an embodiment, as shown in FIGS. 5 and 6, FIGS. 5 and 6 are a schematic plan view of an LED of an embodiment of the present disclosure and a schematic enlarged view of regions IV, V, and VI in FIG. 5, respectively, a spacing between the transparent conductive layer 130 and the second semiconductor layer 123 is between 0.5 μm and 3 μm. By controlling the spacing between the transparent conductive layer 130 and the second semiconductor layer 123 to be between 0.5 μm and 3 μm, the area of the transparent conductive layer 130 can be maximized while ensuring a safe spacing between the transparent conductive layer 130 and the second semiconductor layer 123, thereby ensuring the reliability of the LED. Moreover, the spacing between the transparent conductive layer 130 and the second semiconductor layer 123 is uniform everywhere. Especially at the corners (the first corner C1, the second corner C2, the third corner C3, or the fourth corner C4), for example, the first spacing D1 between the first corner C1 and the transparent conductive layer 130, the second spacing D2 between the first edge E1 and the transparent conductive layer 130, and the third spacing D3 between the fourth corner C4 and the transparent conductive layer 130 are equal. Since the spacing between the transparent conductive layer 130 and the second semiconductor layer 123 is in the micrometer range and there are measurement instrument and human errors, the first spacing D1 being within 75% to 125% of the second spacing D2, and the third spacing D3 being within 75% to 125% of the second spacing D2, are considered as D1 being equal to D2 and D3 being equal to D2. Similarly, a spacing between the transparent conductive layer 130 and the first semiconductor layer 121 being uniform everywhere is also considered to satisfy a measurement error of ±25%.

To ensure that the spacing between the transparent conductive layer 130 and the second semiconductor layer 123 is uniform everywhere, this application employs a single yellow photolithography mask for both the semiconductor stack 120 and the transparent conductive layer 130. The transparent conductive layer 130 is etched inward by using the isotropic principle of wet etching. By controlling an etching time and an etching rate, the spacing between the transparent conductive layer 130 and the second semiconductor layer 123 can be controlled to be between 0.5 μm and 3 μm, and the spacing between the transparent conductive layer 130 and the second semiconductor layer 123 can be ensured to be equal everywhere. Even at some corners, the spacing between the transparent conductive layer 130 and the second semiconductor layer 123 can be ensured to be equal everywhere.

In an embodiment, as shown in FIG. 5, no current blocking layer (i.e., the insulating layer) is disposed between the transparent conductive layer 130 and the second semiconductor layer 123, thereby allowing the transparent conductive layer 130 to be in direct and complete contact with the second semiconductor layer 123.

In an embodiment, as shown in FIG. 5, a fillet radius of each of the four corners of the second semiconductor layer 123 is greater than a fillet radius of each of the four corners of the transparent conductive layer 130. It is also necessary to ensure that the fillet radius of each of the four corners of the second semiconductor layer 123 is greater than 2.5 μm, and the fillet radius of each of the four corners of the transparent conductive layer 130 is greater than 1 μm, otherwise, a tip will appear in the first corner C1 or the second corner C2 of the second semiconductor layer 123, so that a more extreme tip will appear in the fifth corner C5 adjacent to the first corner C1 or a sixth corner C6 adjacent to the second corner C2, so that problems such as tip leakage may occur here.

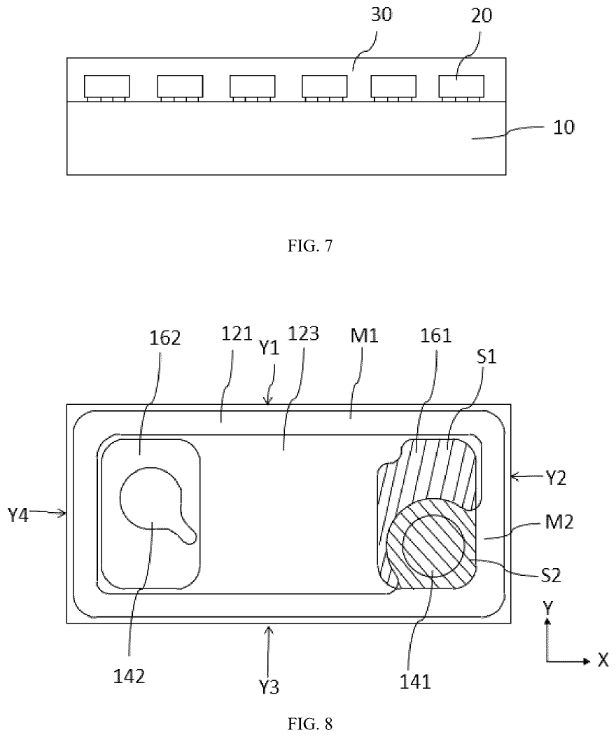

In an embodiment, a light emitting device is provided. Referring to FIG. 7, the light emitting device includes a substrate 10, multiple LEDs 20 disposed on the substrate 10, and an encapsulation layer 30 covering the multiple LEDs 20. The multiple LEDs 20 may be fixed to the substrate 10 by solder paste or the like. Each of the multiple LEDs 20 is the LED described in the above embodiments and thus has the same technical effects described above.

What is claimed is:

1. A light emitting diode (LED), comprising:
a semiconductor stack, comprising a first semiconductor layer, an active layer, and a second semiconductor layer, which are sequentially stacked in that order;
an insulating layer, disposed on the semiconductor stack and having a first opening and a second opening;
a first pad electrode, disposed on the insulating layer and electrically connected to the first semiconductor layer via the first opening; and
a second pad electrode, disposed on the insulating layer and electrically connected to the second semiconductor layer via the second opening;
wherein in a top view of the LED, a ratio of an area of an overlapping region (S1) between a projection of the first pad electrode on the semiconductor stack and a projection of the second semiconductor layer on the semiconductor stack to an area of the first pad electrode is less than 40%.

2. The LED as claimed in claim 1, wherein a ratio of an area of an overlapping region (S2) between the projection of the first pad electrode on the semiconductor stack and a projection of the first semiconductor layer on the semiconductor stack to the area of the first pad electrode is greater than 60%.

3. The LED as claimed in claim 2, wherein the ratio of the area of the overlapping region (S1) between the projection of the first pad electrode on the semiconductor stack and the projection of the second semiconductor layer on the semiconductor stack to the area of the first pad electrode is less than 30%; and the ratio of the area of the overlapping region (S2) between the projection of the first pad electrode on the semiconductor stack and the projection of the first semiconductor layer on the semiconductor stack to the area of the first pad electrode to the area of the first pad electrode is greater than 70%.

4. The LED as claimed in claim 1, further comprising:
a first contact electrode, disposed on the first semiconductor layer; and
a second contact electrode, disposed on the second semiconductor layer;
wherein the insulating layer is disposed to cover the first contact electrode and the second contact electrode, a part of a surface of the first contact electrode is exposed through the first opening of the insulating layer, and a part of a surface of the second contact electrode is exposed through the second opening of the insulating layer;
wherein a surface of the second semiconductor layer comprises a first edge, a second edge, a third edge, and a fourth edge, and the surface of the second semiconductor layer further comprises: a first corner connecting the first edge and the second edge, a second corner connecting the second edge and the third edge, a third corner connecting the third edge and the fourth edge, and a fourth corner connecting the fourth edge and the first edge; and
wherein the first pad electrode comprises a first long side, a first short side, a second long side, and a second short side, which are sequentially connected in that order; an extending direction of the first short side is the same as an extending direction of the first edge of the second semiconductor layer; and an extending direction of the first long side is the same as an extending direction of the second edge of the second semiconductor layer.

5. The LED as claimed in claim 4, wherein the projection of the first pad electrode on the semiconductor stack covers a projection of the second edge on the semiconductor stack, a projection of a part of the first edge on the semiconductor stack, and a projection of a part of the third edge on the semiconductor stack; and a projection of the second pad electrode on the semiconductor stack covers a projection of the fourth edge on the semiconductor stack, a projection of another part of the first edge on the semiconductor stack, and a projection of another part of the third edge on the semiconductor stack.

6. The LED as claimed in claim 4, wherein the projection of the first pad electrode on the semiconductor stack covers projections of the first corner and the second corner on the semiconductor stack, and a projection of the second pad electrode on the semiconductor stack covers projections of the third corner and the fourth corner on the semiconductor stack.

7. The LED as claimed in claim 4, wherein a minimum spacing between the first corner and the first long side of the first pad electrode is a spacing between an extension line (A) of the first corner and the first long side of the first pad electrode, and the extension line (A) is perpendicular to the first short side; and the extension line (A) of the first corner overlaps the first contact electrode, but does not overlap the first opening.

8. The LED as claimed in claim 4, wherein a fillet radius of the first corner is greater than 2.5 μm.

9. The LED as claimed in claim 4, further comprising a transparent conductive layer, disposed on the second semiconductor layer;
wherein the transparent conductive layer comprises a fifth corner adjacent to the first corner of the second semiconductor layer, a minimum spacing between the fifth corner and the first long side of the first pad electrode is a spacing between an extension line (B) of the fifth corner and the first long side of the first pad electrode, and the extension line (B) is perpendicular to the first short side; and the extension line (B) of the fifth corner does not overlap the first contact electrode and does not overlap the first opening.

10. The LED as claimed in claim 9, wherein a fillet radius of the fifth corner is greater than 1 μm.

11. The LED as claimed in claim 7, wherein the spacing between the extension line (A) and the first long side of the first pad electrode is greater than one-half of a length of the first short side of the first pad electrode.

12. The LED as claimed in claim 4, wherein a length of the first edge covered by the projection of the first pad electrode on the semiconductor stack is less than one-half of a length of the first short side of the first pad electrode.

13. The LED as claimed in claim 4, wherein the semiconductor stack comprises a mesa exposing a part of a surface of the first semiconductor layer; the mesa comprises a first region and a second region; and the first region is distributed along the first edge, the third edge, and the fourth edge, and the second region is distributed along the second edge.

14. The LED as claimed in claim 13, wherein a projection of an edge of the first pad electrode on the semiconductor stack is located within the mesa, and a projection of an edge of the second pad electrode on the semiconductor stack is located within the mesa.

15. The LED as claimed in claim 4, wherein the LED comprises a first edge, a second edge, a third edge, and a fourth edge, which are sequentially connected in that order, the LED is symmetric about a central parallel line, and the central parallel line is parallel to each of the first edge and the third edge and is located at a middle position between the first edge and the third edge.

16. The LED as claimed in claim 15, wherein the first contact electrode is symmetric about the central parallel line, and the first opening of the insulating layer is symmetric about the central parallel line.

17. The LED as claimed in claim 15, wherein the overlapping region (S1) between the projection of the first pad electrode on the semiconductor stack and the projection of the second semiconductor layer on the semiconductor stack is symmetric about the central parallel line, and the overlapping region (S2) between the projection of the first pad electrode on the semiconductor stack and the projection of the first semiconductor layer on the semiconductor stack is symmetric about the central parallel line.

18. The LED as claimed in claim 2, wherein the first pad electrode and the second pad electrode are arranged along a first direction, and the overlapping region (S1) and an overlapping region (S2) are arranged along the first direction.

19. The LED as claimed in claim 1, wherein a size of the LED is less than 300 μm×150 μm.

20. A light-emitting module, comprising:
a substrate;
a plurality of LEDs, wherein each of the plurality of LEDs is the LED as claimed in claim 1, and the plurality of LEDs are disposed on the substrate; and
an encapsulation layer, covering the plurality of LEDs.
